(19) United States
(12) Patent Application Publication
(10) Pub. No.: US 2026/0049934 A1
(43) Pub. Date: Feb. 19, 2026

(54) MICROLED ARRAY WITH INTEGRATED PHOTODETECTORS

(71) Applicant: Polymer Forge, Inc, Madison, WI (US)

(72) Inventors: Thomas E. Dillinger, Livermore, CA (US); Daniel L. Burgess, Black Earth, WI (US); Alan A. Pitas, Evansville, WI (US)

(21) Appl. No.: 19/100,437

(22) PCT Filed: Aug. 22, 2023
(86) PCT No.: PCT/US2023/072653

§ 371 Date: Jan. 31, 2025

Related U.S. Application Data
(60) Provisional application No. 63/400,601, filed on Aug. 24, 2022.

(51) Int. Cl. G01N 21/64; G01N 21/76; H01L 25/16; H10F 30/223; H10F 39/90; H10F 55/00; H10F 77/00; H10H 29/24; H10H 29/85

(52) U.S. Cl. CPC G01N 21/6454; H01L 25/167; H10F 55/18; G01N 21/76; H10F 30/223; H10F 39/90; H10F 77/933; H10H 29/24; H10H 29/857

(57) ABSTRACT

Devices and methods for analyzing polymer arrays formed on integrated surfaces of microLEDs. One microarray includes a plurality of individually controllable microLED elements, a plurality of photodetector elements, an integrated surface, and a CMOS driver chip. Each microLED element is paired with a photodetector element. The CMOS driver chip controls activation of the microLED elements and the photodetector elements.

### RELATED APPLICATIONS

This application claims the benefit of U.S. Provisional Ser. No. 63/400,601, filed Aug. 24, 2022, the entire content of which is hereby incorporated by reference.

### SUMMARY

The invention provides devices and methods for analyzing polymer arrays formed on integrated surfaces of microLEDs without the need for separate instrumentation.

Polymer array supports include homogeneous structures based on glass, carbon, plastic, or other materials, and provide a two-dimensional planar surface for the attachment and growth of synthetic polymers. The disclosed invention integrates paired microLEDs and photodetectors into a single array, thereby consolidating the functions of synthesis support structure and fluorescence scanning into a single device. In effect, this innovation constitutes a self-scanning polymer array which removes the need for a separate camera or photodetector array for fluorescence-based analysis of the polymers, avoids associated sources of analysis error, and reduces data management and storage requirements. Additionally, if the photodetector is sensitive to the emitted wavelength of the microLED, an integrated photodetector can serve as a direct test circuit, eliminating the need for a separate photosensitive test fixture.

Accordingly, in some embodiments, the invention provides a microarray device. The device includes a plurality of individually controllable microLED elements, a plurality of photodetector elements, an integrated surface, and a CMOS driver chip. Each microLED element is paired with a photodetector element, and the CMOS driver chip controls activation of the microLED elements and the photodetector elements.

In some embodiments, the microLED elements include an anode, a through via connection to a current spreading layer on top of the anode, and a backside contact to a cathode. In further embodiments, the photodetectors include a through via connection to an anode and a cathode, and the connection provides individual biasing and current sensing from the CMOS driver chip. In certain embodiments, the through via connection includes an attenuation material, e.g., tungsten or copper, that reduces light crosstalk to adjacent microLED elements of the microarray.

In some embodiments, the CMOS driver chip includes timer circuits that control application of a stimulus, e.g., light or chemical reactants, to the surface of the array to induce emission of light from detectable signals bound to polymers on the surface of the array, and subsequent activation of the photodetector elements upon extinction of the stimulus, whereby the photodetector elements detect the signals.

In certain embodiments, the photodetector elements are positioned to avoid detection of light from the paired microLED element. In other embodiments, the photodetector elements are positioned to absorb light emitted by the paired microLED element. Alternatively, or in addition, the photodetectors are positioned to avoid detection of light from an external stimulatory light source. In particular embodiments, a filter material is applied to either a portion of the photodetector elements or to another component of the microarray such that it prevents light from a stimulatory light source from reaching the photodetectors. Filter materials include dielectric materials having a high refractive index, such as, e.g., borosilicate glass, or can be alternating layers of high and low refractive index materials. Such materials include oxides of titanium, chromium, aluminum, zirconium, magnesium, or silicon.

Embodiments of the invention include microarrays comprising polymers that have been synthesized on the integrated surface of the microarray. The polymers are synthesized in an array of features that correspond to the microLED elements. In further embodiments, one or more of the polymers include a detectable label that has either been integrated into the sequence of the polymers or bound to the polymers by binding of, e.g., a labeled probe specific for specified polymers of the array.

In some embodiments, the detectable label emits light (i.e., is luminescent) upon contact by a stimulus and is detected by the photodetector elements of the array. The photodetector elements are made of layered semiconductor materials, e.g., polycrystalline silicon, that form an n-type cathode layer, an intrinsic semiconductor layer, and a p-type anode layer. The intrinsic semiconductor layer absorbs light emitted by the microLED elements at the features having detectable labels bound to the polymers located at those features.

Light-emitting detectable labels suitable for use with the invention include chemiluminescent, bioluminescent, photoluminescent, phosphorescent, or fluorescent labels. In some embodiments, the detectable label is a lanthanide chelate or a lanthanide-doped semiconductor nanocrystal. In other embodiments, the detectable label is Ruthenium.

In certain embodiments, the detectable label is chemiluminescent and comprises luminol, isoluminol, an acridinium ester, a thioester, a sulfonamide, or a phenanthridinium ester. In other embodiments, the detectable label is bioluminescent, i.e., an enzyme that interacts with a substrate to produce light, such as alkaline phosphatase, glucose-6-phosphate dehydrogenase, horseradish peroxidase, Renilla luciferase, or xanthine oxidase.

Suitably, detectable labels emit light having a wavelength of about 350 nanometers (nm) to about 1600 nm, or about 500 nm to about 700 nm.

The invention also provides a method of detecting a label attached to a polymer bound to the surface of a microLED array. The method includes steps of contacting the label with a stimulus, e.g., light, to induce an emission, and detecting the emission by activating a photodetector paired with a microLED of the array. In some embodiments, the stimulus is removed prior to activating the paired photodetector. In some embodiments, the stimulatory light is provided by the microLED array. In further embodiments, the stimulatory light is provided by an external light source, e.g., wherein the external light source strikes the surface at an angle that the light at grazing incidence experiences total internal reflection. In certain embodiments, the angle is greater than 87° from the surface normal.

Other aspects of the invention will become apparent by consideration of the detailed description and accompanying drawings.

### BRIEF DESCRIPTION OF THE DRAWINGS

FIGS. 1A and 1B are schematic drawings depicting the prior method of detecting a synthesized polymer on a solid support with a bound fluorophore (FIG. 1A), using an external light excitation source and external camera to detect fluorophore emission (FIG. 1B).

FIGS. 1C and 1D are schematic drawings showing an exemplary embodiment of the invention incorporating a paired photodetector with each microLED to sense fluorophore emission (FIG. 1C), wherein an external emission detection camera is not required (FIG. 1D).

FIGS. 1E and 1F are schematic drawings showing an exemplary embodiment of the invention wherein the fluorophore is excited by the emission wavelength of the individual microLED, and the signal emission from the flurophore is detected by the paired photodetector (FIG. 1E), and wherein neither an external light excitation source nor an external emission detection camera are required (FIG. 1F).

FIG. 2 is an illustration depicting the cross-section of a microLED with a through-substrate via for connection to the anode.

FIG. 3 is an illustration showing the bonding of the microLED array to a CMOS driver chip.

FIG. 4A is an illustration showing the addition of photodetector paired with the microLED, with through-substrate vias for the photodiode connections.

FIG. 4B is an illustration depicting the connections of the microLED and integrated photodetector to a CMOS driver chip after separation from the sapphire substrate depicted in FIG. 4A.

FIG. 5 is an illustration of an exemplary mask lithography for patterning a microLED with a paired photodetector.

FIG. 6 is an illustration depicting the addition of an anti-reflective coating layer over the microLED array and integrated photodetector wafer surface.

FIG. 7 is an illustration of an exemplary embodiment of the invention wherein mask lithography is carried out in the construction of multiple integrated photodetectors for each microLED.

FIG. 8A is an illustration depicting an exemplary embodiment of the invention wherein a filter layer is applied to the sidewall of a photodetector such that it reflects wavelengths of light, i.e., stimulus wavelengths, and transmits wavelengths of interest, e.g., fluorophore emissions from a probe attached to a polymer bound to the surface of the microarray.

FIG. 8B is an illustration depicting an exemplary embodiment of the invention wherein a filter layer is applied between the current spreading layer of the photodetector and the integrated surface of the microLED, arranged such that it reflects wavelengths of light, i.e., stimulus wavelengths, and transmits wavelengths of interest, e.g., fluorophore emissions from a probe attached to a polymer bound to the surface of the microarray.

FIG. 9 is an illustration showing an exemplary embodiment of the invention where the spatial arrangement of the microLED array elements and the external light excitation source reduces the percentage of excitation light energy reaching the photodetector. The excitation light 191 is directed to the attached fluorophore probe from an acute incident angle, such that the reflected excitation light 192 will be directed away from the photodetector that is actively sensing the fluorophore emission. The fluorophore emission 193 after excitation will be omnidirectional, with a percentage reaching the photodetector 194. Minimizing the excitation light exposure at the active photodetector improves the signal-to-noise ratio.

FIG. 10 is an illustration depicting an exemplary embodiment of the invention wherein the timing of the end of the excitation pulse minimizes residual contribution of the excitation light to the photodetector sense current.

### DETAILED DESCRIPTION

Semiconductor-based microLED arrays are emerging as a compelling technology for solid-phase polymer synthesis applications utilizing photochemistry. As described in WO 2021/167807, a fluidic channel enclosing the surface of the microLED array provides for sequential delivery and removal of the chemical reagents required for polymer synthesis, while selective illumination by individual microLEDs in the microLED array provides activation energy and spatial partitioning for serial photochemical reactions. In this way, large numbers of different polymers such as DNA, RNA, peptides, or other polymers can efficiently be synthesized in parallel attached to the surface of the microLED array within a common reaction vessel sharing the same pool of reagents.

Earlier technologies for conducting solid-phase polymer synthesis with photochemistry utilized similar chemical reagents but differed primarily by the way light was provided to the individual reaction sites. As described in, e.g., U.S. Pat. Nos. 5,143,854; 5,445,934; and 6,375,903, these methods use static or dynamic photomasks to partition light from a single external source into a pattern of independent pixels projected onto a separate solid support, such as the surface of a glass slide contained within a transparent fluidic channel, to control and partition the synthesis reactions.

The microLED array-based approach, as described in, e.g., WO 2021/167807; U.S. Pat. Nos. 7,737,088; and 10,872,924, improves on these previous approaches by utilizing the light source itself as the solid support, thus emitting light that is already partitioned by the selective activation of independently controlled microLEDs within the array. This design obviates the need for separate lenses, mirrors, filters, tapers, or masks to partition and conduct light, thereby reducing instrument cost, size, and complexity, as well as removing multiple potential sources of light scattering that reduce polymer quality.

The integration of the light source into the solid support for the in situ photochemical synthesis provides important advantages over previous approaches for the photochemical synthesis of polymer arrays. However, the subsequent analysis of those polymer arrays using existing fluorescence-based techniques currently requires the use of a fluorescence microscope or array scanner to detect and localize signals emitted from fluorescently labeled probes to precise locations within an array. These techniques are time-consuming and require additional instrumentation, such as a laser-induced fluorescence microscope or array scanner, providing multiple opportunities for error and assay failure. Additionally, these instruments utilize cameras with high resolution photodetector arrays to detect light emitted from the probes, resulting in large image data files that require increased memory storage capabilities and lengthy file transfer times. Furthermore, images of the array obtained by the camera must be carefully aligned to the physical polymer array to accurately determine which polymer is associated with the fluorescent probe signal, requiring suppression of vibration during the image acquisition process.

Innovations that enable the efficient analysis of polymer arrays without requiring this additional instrumentation are needed.

Described herein is a microarray that combines microLEDs with integrated photodetectors in a microarray format, as well as methods of using the microarray to detect a probe attached to a polymer on the surface of the array. Each microLED light source is paired with an individual photodetector, enabling both synthesis of polymers using photochemistry and scanning for fluorophores on a single reaction surface. As used herein, a “microarray” refers to a plurality of features arranged in a pattern, where each feature represents a species of polymer synthesized on an integrated surface of the paired microLEDs and photodetectors.

Applications for the invention include synthesis and analysis of molecular libraries, identification of binding molecules for drug discovery purposes, identification of biomarkers for use in diagnostic applications, identification of structural molecules for use in nanotechnology and nanoconstruction, synthesis and retrieval and sequencing of nucleic acids for the purpose of molecular data storage. Other applications utilize the microarray with specified polymers attached to the surface as a part of an analytical or diagnostic device.

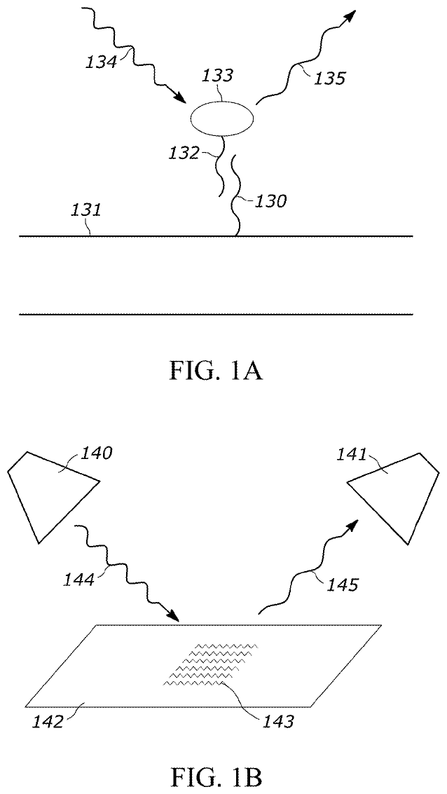

FIGS. 1A-F provide an illustration of how the invention eliminates the need for a separate camera and/or excitatory light source to perform experiments utilizing light-emitting, e.g., fluorescent, probes to analyze polymer arrays.

FIG. 1A provides a general illustration of the prior approach to fluorescent analysis of polymer arrays, where polymers (only a single polymer 130 is shown for clarity) are attached to the surface 131 of a simple solid support (for example, a glass slide) which were previously synthesized using solid-state photochemistry controlled by an external light source (not shown). A probe 132 containing a fluorescent tag 133 is shown bound to the polymer 130. Excitatory light 134 from another external light source (see also FIGS. 1B, 140) stimulates the fluorophore 133 to emit light of a longer wavelength 135 which is then detected by an external camera (see also FIGS. 1B, 141) for subsequent image processing and probe localization within the array.

FIG. 1B provides the macroscopic context for FIG. 1A. A simple solid support 142 contains an array of polymers 143 synthesized in-situ. For fluorescence-based analysis with fluorophore-labeled probes, excitatory light 144 is emitted from an external light source 140 to irradiate the surface of the polymer array. Light 145 emitted from any stimulated fluorophores is then detected by an external camera 141.

FIG. 1C generally represents the concept of the invention. As in FIG. 1A, the surface 160 of the solid support serves as a substrate for a polymer 161 bound to a probe 162 which includes a fluorescent tag 163. In this case, however, the solid support is integrated in a microLED array and individually addressable microLEDs 164 within the array provide the light required to control the photochemical synthesis reactions on its own surface 160. For subsequent analysis, the excitatory light 165 needed to stimulate the fluorophore 163 is similarly supplied from an external light source (see also FIGS. 1D, 172) but the emitted light 166 is detected by the integrated photodetector 167 rather than by a separate external camera.

FIG. 1D provides the macroscopic context for FIG. 1C. The solid support 170 is a microLED array which performs the dual function of providing the light used in the photochemical synthesis of the polymers on its surface and providing the photodetectors used in subsequent fluorescence-based analysis. In this embodiment, excitatory light 171 is similarly provided by an external light source 172 but a separate external camera is not required to detect light emitted by fluorophores from probes bound to the polymers.

FIG. 1E depicts another embodiment of the disclosed invention, where the same wavelength of light 180 that the microLED 181 had previously used to control polymer synthesis is also capable of exciting the fluorescent tag 182 attached to the probe, causing it to emit light 183 that can be detected by the integrated photodetector 184. In this embodiment, the invention obviates the need for both an external light source and external camera to perform fluorescence based analysis of the polymers synthesized on the surface of the microLED array.

FIG. 1F provides the macroscopic context for FIG. 1E. In this embodiment, the same wavelength of light emitted by the microLED array to control polymer synthesis can also be used to stimulate fluorophores in the subsequent analysis of those polymers. For example, 365 nm wavelength light can be used to control the solid-state photochemical synthesis of both DNA and peptide polymers and the fluorophore Marina Blue (6,8-difluoro-7-hydroxy-4-methylcoumarin), which can be used to label many different types of probes, has excitation and emission peaks at 365/460 nm (Sun W C, Gee K R, Haugland R P. Synthesis of novel fluorinated coumarins: excellent UV-light excitable fluorescent dyes. Bioorg Med Chem Lett. 1998 November 17; 8(22): 3107-10). In this embodiment of the invention, a microLED array with integrated photodetectors is used for analysis of the polymers on its surface 190 using fluorescence-based methods without the need of an external light source to excite fluorophores or an external camera for detection and localization of light emitted by those fluorophores. In other embodiments, the use of an external light source enables the selection of fluorophores with peak sensitivity at wavelengths other than 365 nm, such as, for example, 405 nm.

### Structural Components of the Microarray

The components of the microarray include individually controllable microLED elements, photodetector elements that are paired with each microLED element, an integrated surface that provides a substrate for polymer synthesis above the surface, and a CMOS driver chip that controls activation of the microLED elements and the photodetector elements. As used herein, “CMOS,” which is an acronym for “complementary metal-oxide semiconductor,” refers to a technology used for constructing integrated circuit (IC) chips. In the context of the invention, a CMOS driver chip is used to control activation of the microLED elements and the photodetector elements. In some embodiments, the CMOS driver chip also controls application of a stimulus to the surface of the array. The stimulus is used to induce a signal emission from a detectable label bound to one or more polymers of the array, as further described below.

As will be understood by those of skill in the art, the microLED elements are self-illuminating pixels configured from layered semiconductor materials, namely, gallium nitride, that are arranged to form a p-type anode layer, an n-type cathode layer and multiple quantum well layers. In some embodiments, microLEDs include a through via connection to a current spreading layer on top of the anode layer and a backside contact to the cathode. In some embodiments, the through via is annular and circumscribes the microLED.

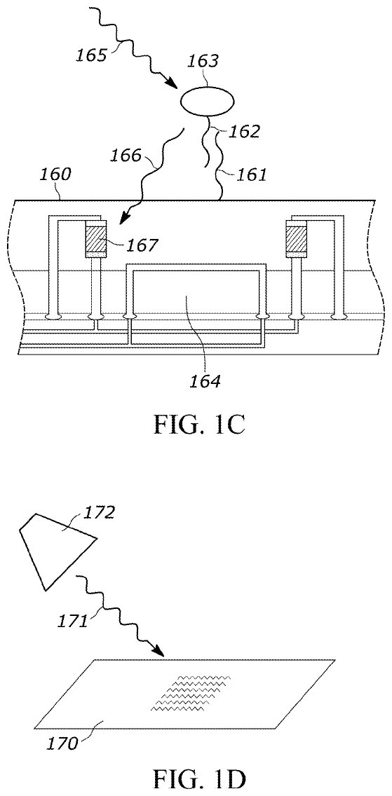

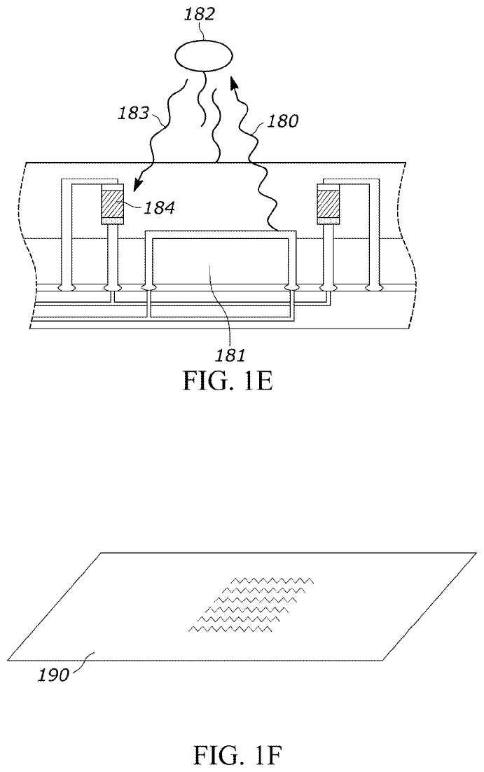

FIG. 2 illustrates a starting cross-section of an individual microLED 101 in a microLED array. A circumferential through-substrate via 102 connects to a current spreading layer 103 on top of the microLED anode 104 and provides a backside connection to a CMOS driver chip (shown in FIG. 3).

FIG. 3 illustrates the top layer of the CMOS driver chip 105 bonded to the backside of the microLED array, with the through-substrate via anode contact 102 and n-type semiconductor cathode metal contact 106 connections from the microLED array to the CMOS driver chip 105.

The through-substrate via 102 is suitably manufactured using integrated circuit process steps for through wafer connections. Initially, the area of the through-substrate via 102 is lithographically patterned. Subsequently, a vertical etch step results in an open trench. An isotropic deposition of a dielectric is followed by anisotropic etching to result in a through-substrate via sidewall dielectric. Metal is then be deposited. A chemical-mechanical polishing step is suitably applied to planarize the microLED array surface.

As there is not a direct method to implement epitaxially-grown semiconductor layers above the microLED to realize a photodetector, a polycrystalline implementation of the photodetector is contemplated. Suitably, the photodetectors are reverse-biased.

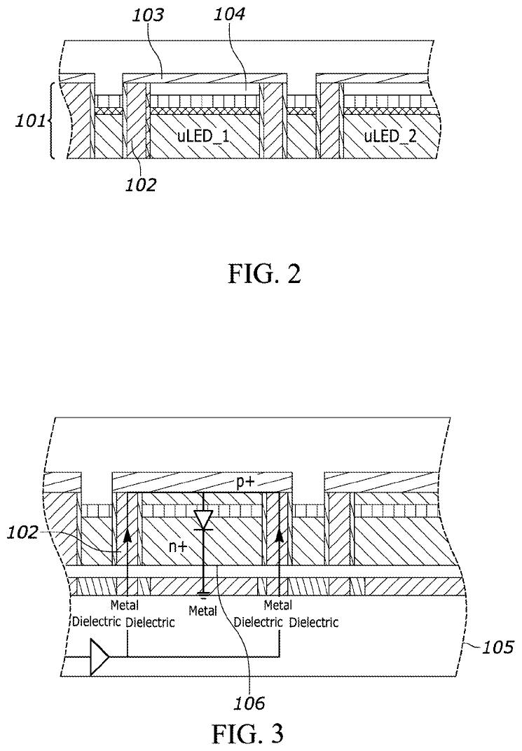

FIGS. 4A and 4B depict the addition of an annular photodetector semiconductor layer stack 107 surrounding the microLED. FIG. 4A illustrates the cross-section of the integrated photodetector structure prior to microLED array backside processing to expose the through-substrate vias. FIG. 4B shows the microLED array structure after backside processing, in preparation for vertical bonding to a CMOS driver chip.

In certain embodiments, the photodetector is constructed from a series of deposited semiconductor layers, with impurity concentrations incorporated during deposition to provide a p-type/intrinsic/n-type (PIN) structure. For example, a series of polycrystalline silicon layers can be deposited to provide a photodetector sensitive to light wavelengths readily absorbed by the intrinsic silicon bandgap energy.

A dielectric layer 108 is present between the microLED surface and the bottom of the photodetector semiconductor structure in FIGS. 4A and 4B. This precludes an epitaxial growth of the photodetector semiconductor layers, which is an exemplary embodiment. The embodiment depicted in FIGS. 4A and 4B reflect the deposition and patterning of a polycrystalline semiconductor. The deposition process step affects the polycrystalline grain size distribution and can be modified to achieve photodetection efficiency.

The contacts to the photodetector are provided with through-substrate vias co-located with the microLEDs. In some embodiments, the through-substrate vias are located circumferentially around the microLED. The through-substrate vias are vertically bonded to matching connections in a CMOS driver chip. The CMOS driver chip can also integrate the circuitry to sense an increase in the reverse-biased photodetector current. An added benefit of the through-substrate vias is that the metal in the photodetector contacts serves to provide additional attenuation of microLED illumination outside the column above the microLED surface, which reduces light crosstalk to adjacent microLED elements.

FIGS. 4A and 4B also illustrate an embodiment where a through-substrate via 109 connects to the n-type photodetector cathode. The processing of this through-substrate via suitably occurs prior to the photodetector cathode layer deposition to provide the electrical contact to the semiconductor n-type material in the photodiode. The thermal budget for the deposition of the cathode layer can thus be limited by the metallurgy used in formation of the through-substrate via contact 109. To increase the allowable thermal budget for polysilicon deposition, a typical embodiment of the through-substrate via contact would use a refractory metal, such as Tungsten.

FIGS. 4A and 4B also depict an embodiment with a taller through-substrate via to provide the anode connection 110 to the top of the photodetector. A conductive current spreading layer 111 is deposited on top of the planarized through-substrate via and planarized p-type anode surface to complete the anode contact. In one embodiment, the bottom part of the anode through-substrate via 112 is concurrently etched with the through-substrate via for the cathode contact. A subsequent photolithography step etches and provides the dielectric sidewall and metal for the remainder of the through-substrate via for the anode contact 113.

A dielectric layer 114 is deposited over the top surface of the photodetector and polished to provide the bottom surface of the fluidic channel (i.e., integrated surface of the microarray) for introduction of reactants. In an embodiment, one or more layers of a spin-on dielectric such as borosilicate glass (BSG) provides an appropriate integrated surface to act as a substrate for polymer synthesis.

The photodetector elements are each paired with a microLED element. In some embodiments, the photodetector elements are paired with the microLED elements in a 1:1 ratio. In other embodiments, there are 2, 3, or 4 photodetector elements for each microLED element (i.e., 1:2, 1:3 or 1:4 ratios).

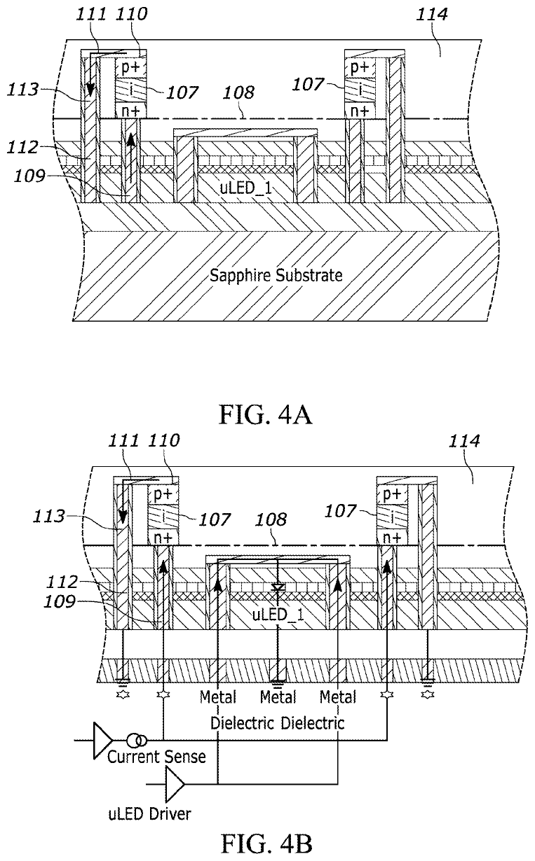

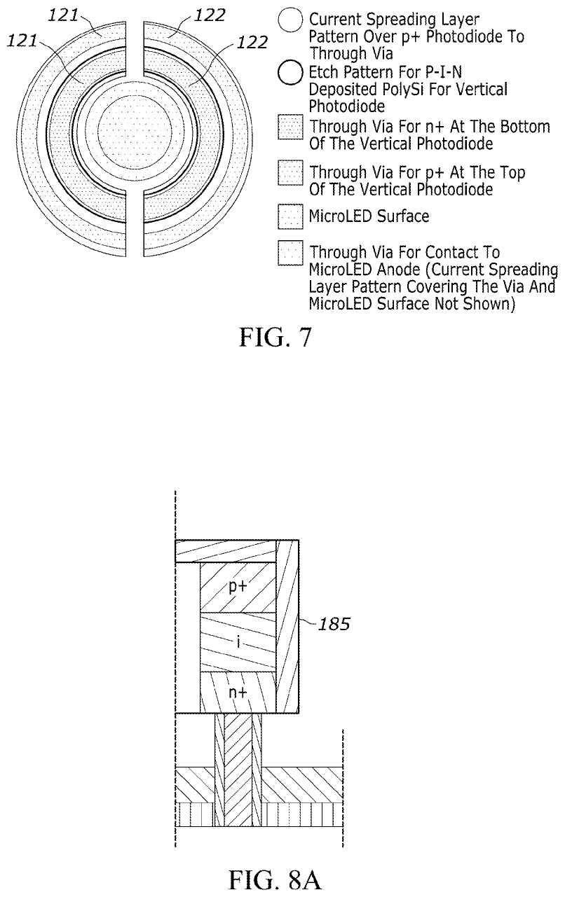

As will be envisioned, the photodetectors may be arranged about the microLEDs in a number of three-dimensional shapes. In some embodiments, each photodetector is arranged in an annular (e.g., cylindrical) pattern around the microLEDs as a ring (see FIG. 5) or interrupted ring (see FIG. 7). In other embodiments, the surrounding photodetectors are arranged as a polygon or interrupted polygon of three or more sides, e.g., three to thirty, or even one hundred sides or more are envisioned.

FIG. 5 illustrates an embodiment of the photolithographic patterning of the microLED and the surrounding photodetector. The inner pattern 115 defines the through-substrate via anode contact for the microLED. The lithographic pattern for the current spreading layer on top of the microLED is derived from the outer perimeter of the through-substrate via. There is a similar annular pattern for the through-substrate vias for the cathode 116 and anode 117 connections to the integrated photodetector, and the current spreading layer 118 that connects the photodetector anode to a through-substrate via. Another lithography pattern 119 defines the lateral dimension of the photodetector, for vertical etching of the deposited PIN layers. As will be appreciated by those of skill in the art, the selection of the width of the photodetector semiconductor PIN layers is a tradeoff between greater incident light sensitivity with a wider dimension versus the reduced microLED areal density in the array. In some embodiments, the area of the photodetector may overlap, or encroach over, the microLED area at each feature.

FIG. 7 illustrates another embodiment of the photodetector, with a design modification to the fully annular topology shown in FIG. 5. The single photodetector in FIG. 5 has been split into multiple electrically separate photodetectors 121 and 122. If the fluorophore excitation light source is oriented at an acute angle to the microLED array surface, the majority of the light reflection energy will be at an acute angle opposite the vertical to the microLED array surface. A fluorophore present above an individual microLED receiving this excitation will emit light in all directions. A photodetector positioned behind the incident light wavefront will receive minimal excitation light energy. Although the photodetector area is reduced in FIG. 7 and will thus reduce the detected fluorophore light emission, the considerable drop in excitation light energy will improve the signal-to-noise ratio of the photodetector current to confirm the presence of the fluorophore attached to the synthesized polymer above the individual microLED.

The microLED elements and paired photodetector elements are arranged in an array of features. Each microLED is individually controllable, thus enabling independent photochemical synthesis reactions to occur at each feature in order to provide polymers of varying length and sequence in an array format. Accordingly, certain embodiments of the microarrays of the invention further include a plurality of polymers synthesized on the integrated surface of the microarray.

The synthesis reactions occur on the integrated surface, and are facilitated by, e.g., a flow cell fixed over the surface. The flow cell is suitably constructed with material transparent to the wavelengths of light used to control the initial photochemical synthesis reactions and to excite fluorophores used in downstream applications. The flow cell suitably includes input and output ports to permit the delivery and removal of fluids comprising chemical reactants, analytes, probes, wash solutions, and waste products from the surface of the microLED array within the reaction chamber. The design and fabrication of an example reaction chamber flow cell was previously described (U.S. Pat. No. 6,375,903, which is incorporated herein by reference in its entirety).

In some embodiments, a commercially-available DNA oligonucleotide synthesizer is connected to the flow cell to deliver the desired sequence of reactants to the reaction chamber for the polymer synthesis reactions and binding of probes. In general, the polymers are synthesized by way of sequential and controlled delivery of monomers or subunits having photolabile protecting groups, whereby the microLED elements control addition of the monomers or subunits to the growing polymer. Suitable monomers include, but are not limited to nucleic acids, nucleotides, oligonucleotides, polynucleotides, amino acids, oligopeptides, nucleomimetics, ribonucleotides, deoxyribonucleotides, peptide nucleic acids, peptides, peptidomimetics, glycopeptides, heteroglycans, proteins, or combinations thereof. In certain embodiments, the polymers are heteropolymers, such as, e.g., oligonucleotides and oligopeptides.

In some embodiments, a detectable label is attached to one or more polymers of the array. As used herein, a “detectable label” refers to a molecule or chemical moiety that produces, either spontaneously or upon stimulation, a signal that can be detected, either directly or indirectly, by a sensor or detector. The label molecule may be attached to another molecule, e.g., a probe, incorporated within it, or linked to it in some traceable fashion, to facilitate detection of the latter. In the context of this definition, “directly” means that the signal travels from the label molecule or moiety directly to the sensor or detector, while “indirectly” means that the signal is relayed, altered, modified, translated, or converted by one or more intermediary molecules, structures, or processes before it reaches the sensor or detector. In cases where the signal from the detectable label is detected indirectly, the intermediary molecules structures or processes are considered to be part of the detectable label.

A fluorescent probe, i.e., a molecule that bears a fluorophore and is capable of binding to a polymer attached to the surface of the microLED array, is one type of detectable label that is suitably used in the context of the invention. As a non-limiting example, the fluorescent probe including the detectable label is a single-stranded deoxyribonucleic acid (DNA) molecule conjugated with a fluorescent 6-carboxyfluorescein (6-FAM) moiety and capable of hydrogen bonding to a complementary single-stranded DNA molecule attached to the surface of the microLED array. As another non-limiting example, the fluorescent probe including the detectable label is a monoclonal antibody attached to a Europium chelate and is capable of recognizing and binding to a specific peptide attached to the surface of the microLED array. In yet another non-limiting example, the fluorescent probe including the detectable label is a disease-associated protein attached to a Terbium chelate and is able to bind to a peptidomimetic molecule attached to the surface of the microLED array, where the peptidomimetic molecule could thus be identified as a potential candidate drug for treating the disease. In still another non-limiting example, the detectable label includes two different fluorophores (a donor fluorophore and an acceptor fluorophore) in a method known as Time Resolved Förster Resonance Energy Transfer (TR-FRET) which enables increased sensitivity for the detection of probe molecule-target molecule interactions by increasing the signal-to-noise ratio compared to standard fluorescence methods.

In some embodiments, the stimulus that induces a detectable signal is a chemical stimulus. In a non-limiting example, an antibody attached to an acridinium ester moiety is allowed to bind to a peptide attached to the surface of the microLED array. The application of hydrogen peroxide causes the chemiluminescent acridinium ester moiety to emit light in the range of 400-500 nm, which is subsequently detected by a photodetector at that feature to determine the spatial location of the probe on the surface of the microLED array. In other non-limiting examples, the detectable label includes an enzyme such as horseradish peroxidase, alkaline phosphatase, or luciferase, each of which can produce light when contacted with an appropriate substrate.

In other embodiments, the stimulus is light, which can be used to activate labels that emit light, or luminescence. Suitably, the luminescent detectable label is chemiluminescent, bioluminescent, photoluminescent, phosphorescent, or fluorescent.

In some embodiments, the detectable label includes a lanthanide chelate or a lanthanide-doped semiconductor nanocrystal. (Temporally and spectrally resolved imaging microscopy of lanthanide chelates. Vereb G, Jares-Erijman E, Selvin P R, Jovin T M. Biophys J. 1998 May; 74(5): 2210-22; Ultrasensitive bioanalytical assays using time-resolved fluorescence detection. Dickson E F, Pollak A, Diamandis E P. Pharmacol Ther. 1995 May; 66(2): 207-35.) Suitably, the lanthanide is Samarium (Sm), Europium (Eu), Terbium (Tb), or Dysprosium (Dy), or a combination of these or other lanthanides may be used.

In other embodiments, the detectable label includes Ruthenium (Ru). (Ruthenium(II) Complex Enantiomers as Cellular Probes for Diastereomeric Interactions in Confocal and Fluorescence Lifetime Imaging Microscopy, Frida R. Svensson, Maria Abrahamsson, Niklas Strömberg, Andrew G. Ewing, and Per Lincoln, Phys. Chem. Lett. 2011, 2, 5, 397-401).

In further embodiments, the detectable label is chemiluminescent. Such labels include, but are not limited to, luminol, isoluminol, acridinium esters, thioesters, sulfonamides, or phenanthridinium esters. Additional suitable labels are bioluminescent and include enzymes that interact with a substrate to produce light, such as alkaline phosphatase, glucose-6-phosphate dehydrogenase, horseradish peroxidase, Renilla luciferase, or xanthine oxidase. (Chemiluminescent and bioluminescent techniques, L J Kricka, Clin. Chem. 1991, 37(9): 1472-1481).

In particular embodiments described further below, the structural components of the microarray are arranged or controlled such that exposure of the photodetectors to light from a detectable signal is maximized, and light from an excitatory stimulus (e.g., light, chemical reactants) is minimized, i.e., background and/or false positive signals are reduced or eliminated.

### Spatial Arrangement of Excitation Stimulus and Photodetectors

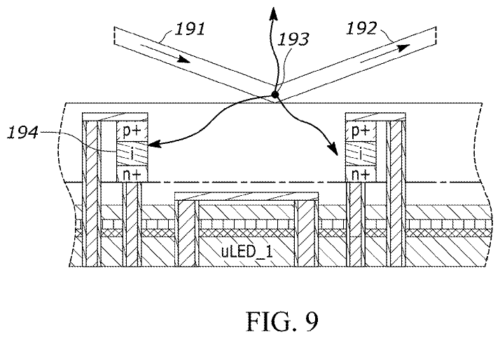

As depicted in FIG. 9, an embodiment of the invention spatially orients the photodetector and the excitation light source such that the photodetector receives minimal excitation light intensity and collects sufficient emission intensity to confirm the local fluorophore attachment to the synthesized polymer above an individual microLED in the microLED array.

For this approach, the external excitation light source is suitably arranged relative to the surface of the microLED such that the light strikes the surface at an angle that the light at grazing incidence experiences total internal reflection. In particular embodiments, the wavefront of the external light source strikes the surface of the microLED array at an angle greater than 87° from the surface normal.

### Temporal Separation of Excitation Stimulus and Photodetector Activation

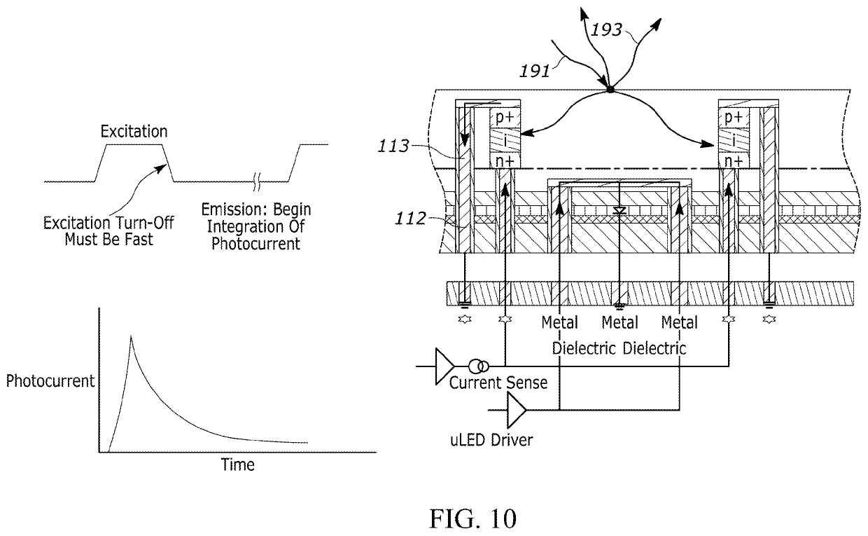

As depicted in FIG. 10, a further embodiment of the invention relies on temporal resolution of excitatory light and label emission to reduce or eliminate non-signal light from reaching the photodetectors. The photodetector current due to the incident label emission will be measured starting after the excitation pulse ends. For luminescence measurements other than photoluminescence, the photodetector current due to incident label emission will be measured starting with the introduction of the corresponding fluidic solution into the channel.

In certain embodiments, the detection of the label involves excitation of the fluorophore, followed by localized detection of fluorescence light emission. In these embodiments, the CMOS driver chip includes timer circuitry to sequentially control emission of a stimulatory light from either an external source (or the microLED elements) and activation of the photodetector elements. Suitably, the timer circuits introduce a time delay between activation of an excitatory light source and the photodetectors, such that the photodetectors are not activated during the period wherein the excitatory light is contacting the surface (i.e., stimulating the detectable labels).

Another embodiment of the integrated photodetector temporally distinguishes between current due to emission from the detectable label and the current from the preceding excitation.

Additional circuitry in the attached CMOS chip would be included to synchronize the photodetector current sense after the trailing edge of the electrical pulse to the circuitry initiating the fluorophore excitation. The typical length of a fluorescent label emission, for example, has a lifetime commonly in the range of one to tens or hundreds of nanoseconds. The integrated photodetector distinguishes the current due to the fluorescent emission from current due to the preceding light excitation that may be incident at the photodetector.

### Filter Materials and/or Anti-Reflective Coatings

In some embodiments, an anti-reflective coating is added to the photodetector semiconductor surface. The anti-reflective coating material properties and thickness of this coating can be modulated to maximize the reflectance of undesirable incident light wavelengths but effectively transmit desirable wavelengths, such as the emission from a fluorescence reaction occurring above the photodetector.

In another embodiment, the signal-to-noise ratio may be optimized by designing the semiconductor layers to have a higher sensitivity at the fluorophore emission light wavelength compared to the excitation light wavelength. Fluorophore materials have a characteristic emission response of wavelength and intensity to different excitation wavelengths. The photodetector and anti-reflection coating filter the excitation wavelength.

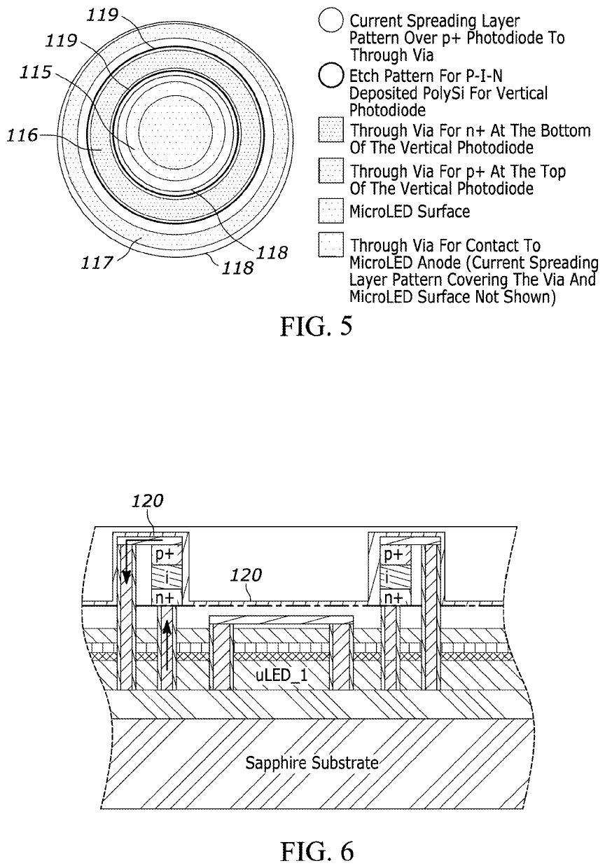

FIG. 6 depicts the cross-section of FIG. 4A, with the addition of an anti-reflective coating 120 on the semiconductor surface of the photodetector. The material selection and thickness of this coating layer can be modulated to maximize reflectance of incident light wavelengths not of interest, with high transmissivity to the incident light wavelengths of interest.

For a silicon-based photodetector, several different dielectric materials are candidates for this anti-reflective coating layer, such as silicon nitride (Si₃N₄) and silicon oxynitride (SiOₓN_{y}, where the x and y are stoichiometric factors for oxygen and nitrogen). The extinction factor for these materials at the microLED emission wavelength is low, with minimal impact to the microLED light intensity, which enables this coating layer to be applied uniformly over the surface, using a process step such as low-pressure chemical vapor deposition (LPCVD) or plasma-enhanced chemical vapor deposition (PECVD). The polycrystalline silicon deposition and annealing process steps are chosen to maximize the polycrystalline grain size distribution for improved PIN photodetector sensitivity.

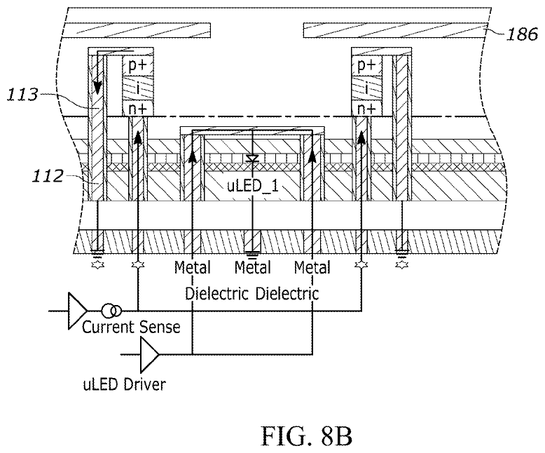

An alternative embodiment to an anti-reflective coating layer on the surface of the microLED and photodetector array is one in which a filter material layer is deposited and patterned in the light path to the photodetector. The thickness and optical material properties of the filter layer are selected to attenuate the excitation wavelength and transmit the fluorophore emission wavelength. FIG. 8A depicts the addition of a patterned filter layer 185 directly on the body of the photodetector. FIG. 8B depicts the addition of a patterned filter layer 186 embedded in the dielectric material between the fluorophore emission and the photodetector.

Unless defined otherwise, all technical and scientific terms used herein are to be interpreted according to the meaning commonly understood by one having ordinary skill in the art.

It should be understood that a description of a numerical value in range format is merely for convenience and brevity and should not be construed as an inflexible limitation on the scope of any embodiments. Accordingly, the description of a range should be considered to have specifically disclosed all the possible subranges as well as individual numerical values within that range to the tenth of the unit unless the context clearly dictates otherwise. Upper and lower limits of intervening ranges may independently be included in the smaller ranges, and are also encompassed within the invention, subject to any specifically excluded limit in the stated range. Where the stated range includes one or both limits, ranges excluding either or both of those included limits are also included in the invention, unless the context clearly dictates otherwise.

Unless specifically stated or obvious from context, as used herein, the term “about” in reference to a number or range of numbers is understood to mean the stated number and numbers +/−10% thereof, or 10% below the lower listed limit and 10% above the higher listed limit for the values listed for a range.

As used herein, the singular forms “a,” “an” and “the” are intended to include the plural forms as well, unless the context clearly indicates otherwise.

All publications, patents, and patent applications referenced in this specification are incorporated by reference.

### EXAMPLE 1

A 10×10 array of individually addressable (activatable) microLED elements paired with integrated photodetectors is fabricated according to the illustrations provided herein (FIGS. 2-6). The individual microLED elements have diameters of 50 μm on a 100 μm pitch. The dimensions of the array are 1 mm×1 mm. The p-and n-layers of the microLEDs are composed of gallium-nitride (GaN) compounds that can be electrically stimulated by the bonded CMOS driver chip to emit light with a peak wavelength of approximately 365 nm. The CMOS driver chip is connected to an electrical power supply and a computer operated controller to control the activation, inactivation, and intensity of light emitted from each microLED in the array. The top layer of the array is substantially planar and is constructed of spin-on borosilicate glass extending 5 mm in each direction beyond the border of the active elements of the array. This extra border space provides for the attachment of a flow cell which encloses the surface of the microLED array to create a reaction chamber. The specific techniques required to fabricate a microLED-photodetector array with the structure illustrated in the enclosed FIGS. (including photolithographic masking, etching, metal organic chemical vapor deposition (or “MOCVD”), electroplating deposition, chemical-mechanical polishing, spin-coating, laser lift-off, dicing, and flip-chip bonding) are established and will be readily understood by persons having skill in the art.

### EXAMPLE 2

The use of the invention for the solid-state synthesis of a complex set of polymers on the surface of the microLED array and use of the paired integrated photodetectors in the subsequent detection of fluorescently labeled probes bound specifically to those polymers, are demonstrated by the following experiment:

### Synthesis

Unless otherwise indicated, the detailed methods and protocols for the synthesis process, including the chemical reagents used, the reaction conditions, and the order of individual steps, have been previously described (see WO 2021/167807; Sack M, Hölz K, Holik A K, Kretschy N, Somoza V, Stengele K P, Somoza M M. Express photolithographic DNA microarray synthesis with optimized chemistry and high efficiency photolabile groups, J Nanobiotechnology. 2016 March 2; 14:14).

The source of the light used to control the photochemistry is an array of individually addressable microLEDs emitting already partitioned ˜365 nm wavelength light (rather than a ˜365 nm point source where the light must subsequently be partitioned, as in the prior methods) and the physical support for the polymer synthesis is the surface of the microLED array (rather than a separate physical support (e.g. made of glass, plastic, or silicon) that is separate from the light source, as in the prior methods).

A set of single-stranded DNA oligonucleotides are synthesized on the surface of a 10×10 microLED array constructed as described in Example 1, with a different oligonucleotide associated with each different microLED. Each microLED in the array is paired with a single photodetector element in a 1:1 ratio (the photodetector is not required for the polymer synthesis process but will be used in the subsequent analysis of the synthesized polymers). The oligonucleotides will be approximately 50 nucleotides in length and composed of a mixture of four DNA bases: adenine (A), cytosine (C), guanine (G), and thymine (T) arranged in a specific pre-determined sequence.

### Analysis

A chemiluminescent acridinium-labeled single-stranded DNA oligonucleotide probe is obtained from a commercial supplier (Integrated DNA Technologies, IDT, Coralville, Iowa). The probe is between 15 and 30 nucleotides in length and has a nucleotide sequence that is complementary to sequence contained within one of the single-stranded DNA oligonucleotides synthesized on the surface of the microLED array. The labeled probe is delivered to the surface of the microLED array under conditions appropriate for hybridization specifically to the synthesized DNA oligonucleotide containing the complementary sequence, followed by a series of washing steps to remove any non-specifically bound probe. Methods and protocols for hybridization of labeled oligonucleotide probes to polymer arrays are established and will be readily understood by those of skill in the art.

The location of the labeled probe (corresponding to only one of the n=100 microLEDs in the array) is detected by delivering hydrogen peroxide to the surface of the array such that it contacts and excites the acridinium label to emit light between 400 and 500 nm in wavelength. Detection of the light emitted by the stimulated fluorophore is detected only by the photodetector associated with the microLED at the same location. The signal from the photodetector is relayed through a signal processor to an attached computer.

The specific fluorescent signal is detected only from the location where the oligonucleotide specifically targeted by the probe was synthesized on the array and is not detected from other locations bearing different oligonucleotides.

### EXAMPLE 3

The same experiment described in Example 2 is carried out, except that the chemiluminescent acridinium label on the probe is replaced with a photoluminescent Europium chelate label (PerkinElmer, Waltham, MA) and the location of the labeled probe (corresponding to only one of the n=100 microLEDs in the array) is detected by irradiating the surface of the microLED array with 365 nm (UV) light. The UV light will excite the Europium chelate fluorophore to emit light between 400 and 500 nm in wavelength. Detection of the light emitted by the stimulated Europium chelate is detected only by the photodetector associated with the microLED at the same location. The signal from the photodetector is relayed through a signal processor to an attached computer.

The specific fluorescent signal is detected only from the location where the oligonucleotide specifically targeted by the probe was synthesized on the array and is not detected from other locations bearing different oligonucleotides. If necessary, a series of experiments will be conducted to improve the signal-to-noise ratio for the detection of fluorophore emission by varying photodetector wavelength selectivity, spatial orientation of the photodetector relative to the light excitation and emission sources, and/or temporal filtering of the excitation then emission sequence.

### EXAMPLE 4

The microLED array of Example 2 is used to control the photochemical synthesis of a population of peptides on its surface and the paired integrated photodetectors are used to detect the specific binding of a fluorescently labeled antibody to those peptides containing the epitope specific to the labeled antibody.

### EXAMPLE 5

Other types of assays, wherein the detection of fluorescent signals linked to molecules synthesized on the surface of the arrays, or molecules interacting with them, are carried out using microarrays described herein. Such assays include, but are not limited to, Polymerase Chain Reaction (PCR) (and variants thereof), fluorescence resonance energy transfer (FRET), and other methods of proximity detection, and various methods of nucleic acid sequencing which utilize fluorescence as the output signal.

Thus, embodiments provided herein describe, among other things, systems and methods for analyzing polymer arrays formed on integrated surfaces of microLEDs. Various features and advantages are set forth in the following claims.

What is claimed is:

1. A microarray comprising:
a plurality of individually controllable microLED elements,
a plurality of photodetector elements,
an integrated surface, and
a CMOS driver chip,
wherein each microLED element is paired with a photodetector element, and wherein the CMOS driver chip controls activation of the microLED elements and the photodetector elements.

2. The microarray of claim 1, wherein the CMOS driver chip comprises timer circuits.

3. The microarray of claim 2, wherein the timer circuits control:
application of a stimulus to the surface of the array, and
activation of the photodetector elements upon extinction of the stimulus.

4. The microarray of claim 1, wherein each photodetector element is positioned to avoid detection of light emitted from the paired microLED element.

5. The microarray of claim 1, wherein each photodetector element is positioned to avoid detection of light emitted from an external stimulatory light source.

6. The microarray of claim 1, further comprising a filter material that prevents light from a stimulatory light source from reaching the photodetector elements.

7. The microarray of claim 6, wherein the filter material is applied to at least a portion of the photodetectors.

8. The microarray of claim 6, wherein the filter material comprises a dielectric material having a high refractive index.

9. The microarray of claim 8, wherein the dielectric material comprises borosilicate glass.

10. The microarray of claim 6, wherein the filter material comprises alternating layers of high refractive index and low refractive index materials.

11. The microarray of claim 10, wherein the filter material comprises layered oxides of titanium, chromium, aluminum, zirconium, magnesium, or silicon, or combinations thereof.

12. The microarray of claim 1, further comprising a plurality of polymers synthesized on the integrated surface of the microarray, wherein the polymers are arranged in an array of features corresponding to the microLED elements.

13. The microarray of claim 12, wherein one or more of the polymers comprises a detectable label.

14. The microarray of claim 13, wherein the detectable label is attached to a subunit of one or more of the polymers or is attached to a probe bound to one or more of the polymers.

15. The microarray of claim 13, wherein the detectable label is luminescent.

16. The microarray of claim 15, wherein the detectable label is chemiluminescent, bioluminescent, photoluminescent, phosphorescent, or fluorescent.

17. The microarray of claim 15, wherein the detectable label is photoluminescent and comprises a lanthanide chelate, a lanthanide-doped semiconductor nanocrystal, or Ruthenium.

18. The microarray of claim 15, wherein the detectable label is chemiluminescent and comprises luminol, isoluminol, an acridinium ester, a thioester, a sulfonamide, or a phenanthridinium ester.

19. The microarray of claim 15, wherein the detectable label is bioluminescent and comprises alkaline phosphatase, glucose-6-phosphate dehydrogenase, horseradish peroxidase, Renilla luciferase, or xanthine oxidase.

20. The microarray of claim 1, wherein each microLED element comprises an anode, a through via connection to a current spreading layer on top of the anode, and a backside contact to a cathode.

21. The microarray of claim 1, wherein each photodetector element comprises a through via connection to an anode and a cathode of the photodetector, and wherein the connection provides individual biasing and current sensing from the CMOS driver chip.

22. The microarray of claim 21, wherein the through via connection comprises an attenuation material that reduces light crosstalk to adjacent microLED elements of the microarray.

23. The microarray of claim 22, wherein the attenuation material comprises tungsten or copper.

24. The microarray of claim 1, wherein the photodetector elements comprise a semiconductor material that absorbs light emitted by a detectable label bound to one or more polymers attached to the integrated surface.

25. The microarray of claim 24, wherein the photodetector elements comprise an n-type cathode layer, an intrinsic semiconductor layer, and a p-type anode layer, wherein the layers comprise polycrystalline silicon.

26. The microarray of claim 24, wherein the detectable label emits light having a wavelength of about 350 nm to about 1600 nm.

27. The microarray of claim 26, wherein the detectable label emits light having a wavelength of about 500 nm to about 700 nm.

28. The microarray of claim 25, wherein the intrinsic semiconductor layer absorbs light emitted by the microLED element.

29. A method of detecting a label attached to a polymer on a surface of a microLED array comprising:
a) contacting the label with a stimulus to induce an emission from the label; and
b) detecting the emission by activating a photodetector paired with a microLED of the array.
The method of claim 29, further comprising a step of removing the stimulus prior to step b).

30. The method of claim 29, wherein the stimulus is light.

31. The method of claim 31, wherein the stimulatory light is provided by the microLED array.

32. The method of claim 31, wherein the stimulatory light is provided by an external light source.

33. The method of claim 33, wherein the external light source strikes the surface at an angle that the light at grazing incidence experiences total internal reflection.

34. The method of claim 34, wherein the wavefront of the external light source strikes the surface of the microLED array at an angle greater than 87° from the surface normal.

35. The method of claim 31, wherein the photodetector is positioned to avoid exposure to the stimulatory light.

36. The method of claim 31, wherein the photodetector is sensitive to a wavelength of the emission and is not sensitive to a wavelength of the stimulatory light.

37. The method of claim 29, wherein the stimulus is a chemical moiety that contacts the label to induce a reaction that produces a chemiluminescent emission.
